(19) United States
(12) Patent Application Publication
(10) Pub. No.: US 2025/0022951 A1
(43) Pub. Date: Jan. 16, 2025

(54) SEMICONDUCTOR DEVICE AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Kentaro ICHINOSEKI, Higashimurayama Tokyo (JP)

(21) Appl. No.: 18/583,336

(22) Filed: Feb. 21, 2024

(30) Foreign Application Priority Data
Jul. 13, 2023 (JP) 2023-115138

(51) Int. Cl. H01L 29/78; H01L 29/06; H01L 29/423; H01L 29/66

(52) U.S. Cl. CPC H01L 29/7813; H01L 29/0696; H01L 29/4236; H01L 29/66734

(57) ABSTRACT

The gate electrode includes a first side surface portion facing a region of a side surface of a mesa part, a second side surface portion positioned at a side opposite to the first side surface portion, a bottom portion oblique to the first and second side surface portions, the bottom portion connecting the first side surface portion and the second side surface portion, a first corner portion positioned between the first side surface portion and the bottom portion, and a second corner portion positioned between the second side surface portion and the bottom portion. An angle between a first straight line and a second straight line is not more than 60°. The first straight line is a straight line extending in a first direction and passing through the first corner portion. The second straight line is a straight line passing through the first and second corner portions.

### CROSS-REFERENCE TO RELATED APPLICATION

This application is based upon and claims the benefit of priority from Japanese Patent Application No. 2023-115138, filed on Jul. 13, 2023; the entire contents of which are incorporated herein by reference.

### FIELD

Embodiments described herein relate generally to a semiconductor device and a method for manufacturing a semiconductor device.

### BACKGROUND

Semiconductor devices that have trench gate structures in which a gate electrode is located inside a trench formed in a semiconductor layer are widely used for, for example, power control.

### BRIEF DESCRIPTION OF THE DRAWINGS

FIG. 1 is a schematic cross-sectional view of a semiconductor device of an embodiment;

FIG. 2 is a graph showing simulation results of a sensitivity of Qgd fluctuation to a fluctuation of a position of a first corner portion of a gate electrode; and

FIG. 3 to FIG. 9 are schematic cross-sectional views showing a method for manufacturing the semiconductor device of the embodiment.

### DETAILED DESCRIPTION

According to one embodiment, a semiconductor device includes a semiconductor layer including a first semiconductor part of a first conductivity type, a second semiconductor part located on the first semiconductor part, the second semiconductor part being of a second conductivity type, a third semiconductor part located on the second semiconductor part, the third semiconductor part being of the first conductivity type, and a mesa part including the third semiconductor part, the second semiconductor part, and a portion of the first semiconductor part, the mesa part extending in a first direction; a gate electrode facing a side surface of the mesa part; and a first insulating part located between the gate electrode and the side surface of the mesa part. The gate electrode includes a first side surface portion facing a region of the side surface of the mesa part including at least the second semiconductor part, a second side surface portion positioned at a side opposite to the first side surface portion in a second direction orthogonal to the first direction, a bottom portion oblique to the first and second side surface portions, the bottom portion connecting the first side surface portion and the second side surface portion, a first corner portion positioned between the first side surface portion and the bottom portion, and a second corner portion positioned between the second side surface portion and the bottom portion. An angle between a first straight line and a second straight line is not more than 60°. The first straight line is a straight line extending in the first direction and passing through the first corner portion. The second straight line is a straight line passing through the first and second corner portions.

Embodiments will now be described with reference to the drawings. The same configurations are marked with the same reference numerals in the drawings. Although the first conductivity type is an n-type and the second conductivity type is a p-type in the description of the embodiments described below, the first conductivity type may be the p-type, and the second conductivity type may be the n-type.

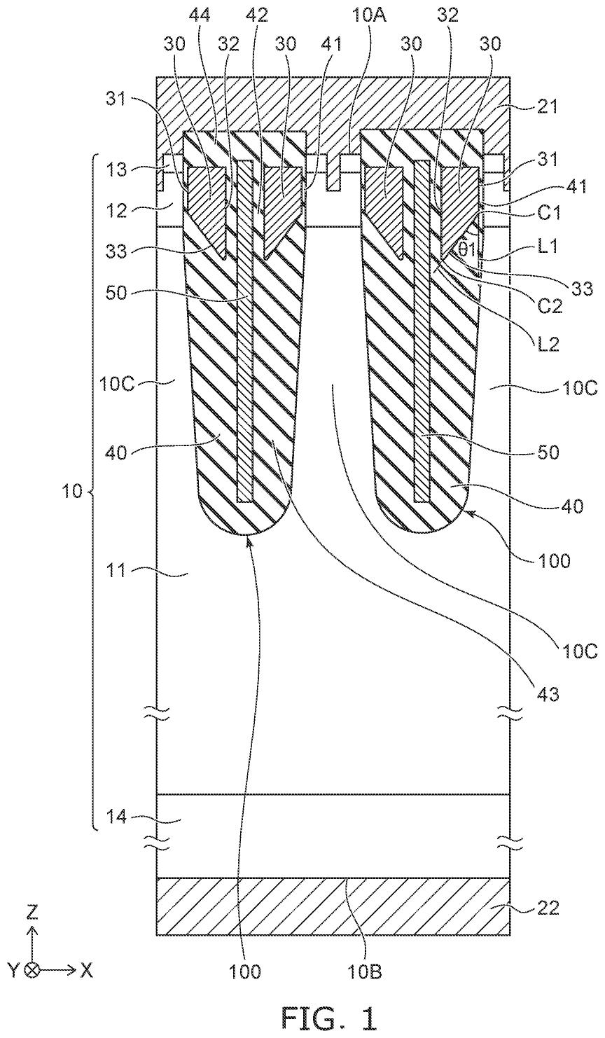

As shown in FIG. 1, a semiconductor device of an embodiment includes a semiconductor layer 10 and a trench structure part 100.

The semiconductor layer 10 includes a first surface 10A, and a second surface 10B positioned at the side opposite to the first surface 10A in a first direction Z. The first direction Z connects the first surface 10A and the second surface 10B with a shortest distance. In FIG. 1, a direction orthogonal to the first direction Z is taken as a second direction X. A direction orthogonal to the first and second directions Z and X is taken as a third direction Y. The first direction Z toward the first surface 10A is taken as “up/upward/above/higher than”, and the first direction Z toward the second surface 10B is taken as “down/downward/below/lower than”.

For example, silicon can be used as the material of the semiconductor layer 10. Or, for example, silicon carbide, gallium nitride, etc., may be used as the material of the semiconductor layer 10.

The semiconductor layer 10 includes an n-type first semiconductor part 11, a p-type second semiconductor part 12 located on the first semiconductor part 11, and an n-type third semiconductor part 13 located on the second semiconductor part 12. The n-type impurity concentration of the third semiconductor part 13 is greater than the n-type impurity concentration of the first semiconductor part 11.

The semiconductor layer 10 includes the third semiconductor part 13, the second semiconductor part 12, and a portion of the first semiconductor part 11, and includes a mesa part 10C extending in the first direction Z. The first surface 10A includes the upper surface of the mesa part 10C. The upper surface of the mesa part 10C includes the upper surface of the third semiconductor part 13. The mesa part 10C extends in the third direction Y. For example, multiple mesa parts 10C are arranged to be separated from each other in the second direction X. Or, multiple columnar mesa parts 10C may be arranged in the second and third directions X and Y.

The trench structure part 100 is positioned inside the semiconductor layer 10 at the first surface 10A side. For example, the trench structure part 100 extends in the third direction Y. For example, multiple trench structure parts 100 are arranged inside the semiconductor layer 10 to be separated from each other in the second direction X. Or, multiple columnar trench structure parts 100 may be arranged in the second and third directions X and Y.

For example, the trench structure part 100 and the mesa part 10C of the semiconductor layer 10 are alternately arranged in the second direction X. The trench structure part 100 is adjacent to the mesa part 10C in the second direction X. The trench structure part 100 is positioned between the mesa parts 10C adjacent to each other in the second direction X. The mesa part 10C is positioned between the trench structure parts 100 adjacent to each other in the second direction X.

The trench structure part 100 includes a gate electrode 30 and an insulating member 40.

The gate electrode 30 faces the side surface of the mesa part 10C in the second direction X. The side surface of the mesa part 10C includes the side surface of a portion of the first semiconductor part 11, the side surface of the second semiconductor part 12, and the side surface of the third semiconductor part 13. For example, conductive polycrystalline silicon can be used as the material of the gate electrode 30.

The gate electrode 30 includes a first side surface portion 31, a second side surface portion 32, a bottom portion 33, a first corner portion C1, and a second corner portion C2.

The first side surface portion 31 faces a region of the side surface of the mesa part 10C including at least the second semiconductor part 12. In the example shown in FIG. 1, the position in the first direction Z of the upper end of the first side surface portion 31 is positioned further toward the third semiconductor part 13 side than the boundary between the second semiconductor part 12 and the third semiconductor part 13.

The second side surface portion 32 is positioned at the side opposite to the first side surface portion 31 in the second direction X. The length in the first direction Z of the second side surface portion 32 is greater than the length in the first direction Z of the first side surface portion 31.

The bottom portion 33 is oblique to the first and second side surface portions 31 and 32 and connects the first side surface portion 31 and the second side surface portion 32. When viewed in cross-section, the shape of the bottom portion 33 is not limited to linear and may be curved, convex, concave, or a combination of two or more such shapes.

The first corner portion C1 is positioned between the first side surface portion 31 and the bottom portion 33. For example, the angle between the first side surface portion 31 and the bottom portion 33 inside the gate electrode 30 (the interior angle of the first corner portion C1) is greater than 90°.

The second corner portion C2 is positioned between the second side surface portion 32 and the bottom portion 33. For example, the angle between the second side surface portion 32 and the bottom portion 33 inside the gate electrode 30 (the interior angle of the second corner portion C2) is less than 90°. The position in the first direction Z of the second corner portion C2 is positioned lower than the position in the first direction Z of the first corner portion C1.

The insulating member 40 includes a first insulating part 41 located between the gate electrode 30 and the side surface of the mesa part 10C of the semiconductor layer 10. The maximum thickness in the second direction X of the first insulating part 41 between the first side surface portion 31 of the gate electrode 30 and the side surface of the mesa part 10C is less 25 than the maximum thickness in the second direction X of the first insulating part 41 between the bottom portion 33 of the gate electrode 30 and the side surface of the mesa part 10C.

The trench structure part 100 may further include a conductive member 50. The conductive member 50 faces the second side surface portion 32 of the gate electrode 30 in the second direction X and extends further downward in the first direction Z than the bottom portion 33 of the gate electrode 30. For example, conductive polycrystalline silicon can be used as the material of the conductive member 50.

One trench structure part 100 includes, for example, two gate electrodes 30 positioned to be separated from each other in the second direction X. For example, the conductive member 50 is positioned between the second side surface portions 32 of the two gate electrodes 30. The conductive member 50 extends downward from a portion positioned between the two gate electrodes 30.

The conductive member 50 is electrically connected with a first electrode 21 described below. Or, the potential that is applied to the conductive member 50 may be lower than the potential applied to a second electrode 22 (described below), which is higher than that of the first electrode 21. The conductive member 50 can increase the breakdown voltage by relaxing the electric field (the vertical electric field) applied in the first direction Z.

The insulating member 40 is positioned between the gate electrode 30 and the semiconductor layer 10, between the conductive member 50 and the semiconductor layer 10, and between the gate electrode 30 and the conductive member 50. For example, silicon oxide can be used as the material of the insulating member 40.

In addition to the first insulating part 41 described above, the insulating member 40 further includes a second insulating part 42, a third insulating part 43, and a fourth insulating part 44.

The second insulating part 42 is positioned between the conductive member 50 and the second side surface portion 32 of the gate electrode 30 in the second direction X.

The third insulating part 43 is located between the conductive member 50 and the first semiconductor part 11 of the semiconductor layer 10.

In the first direction Z, the fourth insulating part 44 is positioned between the gate electrode 30 and the first electrode 21 and between the conductive member 50 and the first electrode 21.

The semiconductor device of the embodiment further includes the first electrode 21 located in the first surface 10A, and the second electrode 22 located in the second surface 10B. The first electrode 21 contacts the third semiconductor part 13 and is electrically connected with the third semiconductor part 13. The first electrode 21 contacts the second semiconductor part 12 and is electrically connected with the second semiconductor part 12.

The semiconductor layer 10 can further include an n-type fourth semiconductor part 14 located between the second electrode 22 and the first semiconductor part 11. The n-type impurity concentration of the fourth semiconductor part 14 is greater than the n-type impurity concentration of the first semiconductor part 11. The fourth semiconductor part 14 is electrically connected with the second electrode 22.

For example, the semiconductor device of the embodiment has a MOSFET (Metal-Oxide-Semiconductor Field Effect Transistor) structure. For example, the first electrode 21 functions as a source electrode; the second electrode 22 functions as a drain electrode; the first semiconductor part 11 functions as a drift layer; the second semiconductor part 12 functions as a base layer; the third semiconductor part 13 functions as a source layer; and the fourth semiconductor part 14 functions as a drain layer.

An n-type inversion layer (a channel) is formed in the portion of the second semiconductor part 12 facing the first side surface portion 31 of the gate electrode 30 when a first potential (e.g., a ground potential) is applied to the first electrode 21, a second potential (e.g., a positive potential) that is greater than the first potential is applied to the second electrode 22, and a gate voltage that is not less than a threshold is applied to the gate electrode 30. Then, a current flows between the second electrode 22 (the drain electrode) and the first electrode 21 (the source electrode) via the fourth semiconductor part 14 (the drain layer), the channel, and the third semiconductor part 13 (the source layer).

According to the embodiment, an angle θ1 between a first straight line L1 and a second straight line L2 is not more than 60°, wherein the first straight line L1 is a straight line extending in the first direction Z and passing through the first corner portion C1 of the gate electrode 30, and the second straight line L2 is a straight line passing through the first and second corner portions C1 and C2.

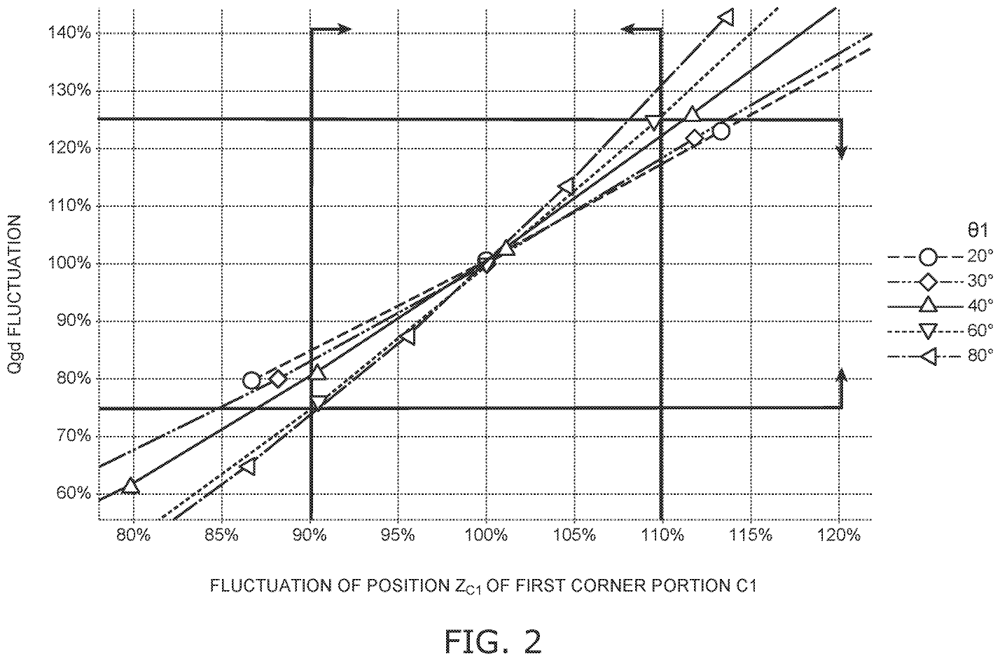

FIG. 2 is a graph showing simulation results of the sensitivity of Qgd fluctuation to the fluctuation of the position in the first direction Z of the first corner portion C1 of the gate electrode 30 when the angle θ1 described above is changed to 20°, 30°, 40°, 60°, and 80°.

The horizontal axis is the fluctuation of a position Z_{C1} in the first direction Z of the first corner portion C1 of the gate electrode 30. The position Z_{C1} of the first corner portion C1 that gives the same on-resistance is set to 100% for each angle θ1 of 20°, 30°, 40°, 60°, and 80°. To maintain the same on-resistance, the position Z_{C1} of the first corner portion C1 moves toward the first surface 10A (upward) as the angle θ1 decreases.

The vertical axis is the fluctuation of the charge amount Qgd between the gate electrode 30 and the first semiconductor part 11 (hereinbelow, also called the gate-drain charge amount). Qgd is set to 100% when the position Z_{C1} of the first corner portion C1 is 100%.

Qgd is one parameter that affects the characteristics of the semiconductor device, and affects the switching loss when switching the semiconductor device on and off by switching the gate voltage applied to the gate electrode 30. It is therefore desirable to set Qgd within a prescribed range. To reduce the switching loss, it is desirable to suppress the Qgd fluctuation to be not more than ±25% when the fluctuation of the position Z_{C1} of the first corner portion C1 is ±10%.

From the results of FIG. 2, the Qgd fluctuation can be set to be not more than ±25% by setting the angle θ1 between the first straight line L1 and the second straight line L2 to be not more than 60°. The Qgd fluctuation can be set to be less than ±25% also by setting the angle θ1 to be not more than 40°.

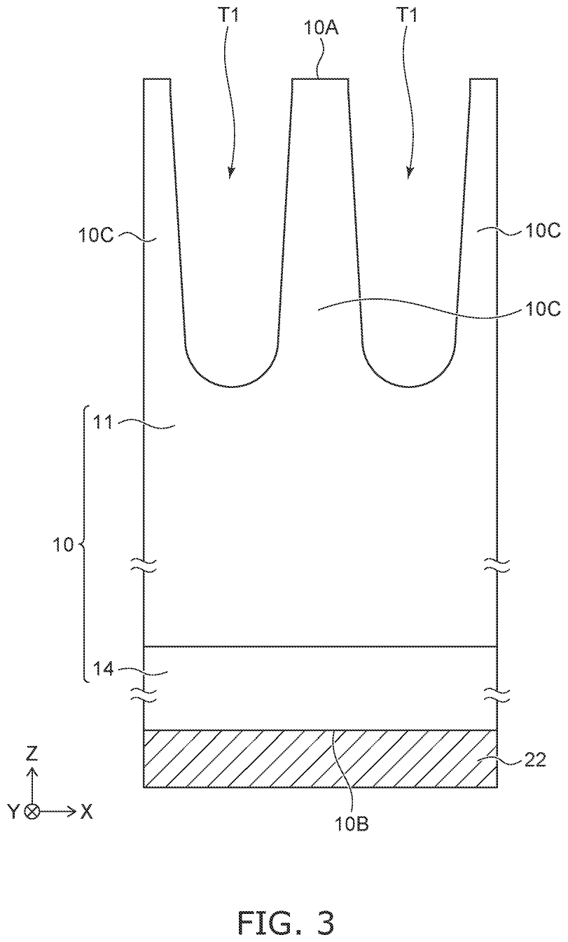

A method for manufacturing the semiconductor device of the embodiment will now be described with reference to FIGS. 3 to 9.

As shown in FIG. 3, the method for manufacturing the semiconductor device of the embodiment includes a process of forming a first trench T1 and the mesa part 10C in the semiconductor layer 10. For example, the first trench T1 is formed by RIE (Reactive Ion Etching).

The first trench T1 extends in the first direction Z from the first surface 10A of the semiconductor layer 10. The mesa part 10C is adjacent to the first trench T1 in the second direction X. For example, the multiple first trenches T1 and the multiple mesa parts 10C each are alternately arranged in the second direction X.

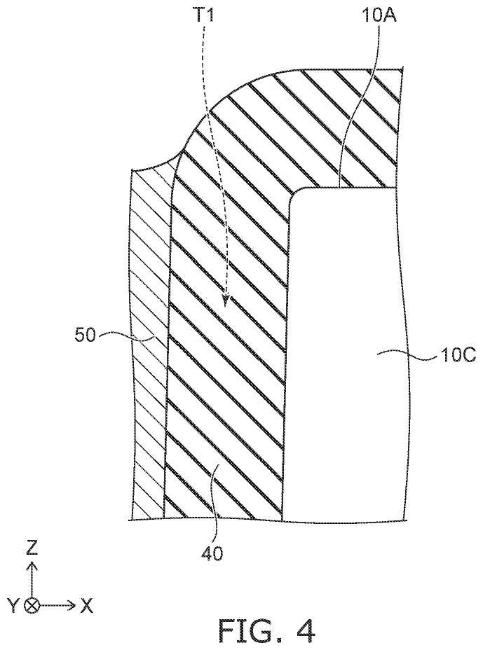

FIGS. 4 to 9 show subsequent processes, and show an enlarged portion at the first surface 10A side at which the first trench T1 and the mesa part 10C are adjacent to each other.

The method for manufacturing the semiconductor device of the embodiment includes a process of forming the insulating member 40 inside the first trench T1. As shown in FIG. 4, the insulating member 40 covers the side surface of the mesa part 10C (the sidewall of the first trench T1) and the first surface 10A. The insulating member 40 covers the bottom wall of the first trench T1. The insulating member 40 is formed along the two sidewalls of the first trench T1 facing each other in the second direction X, and along the bottom wall of the first trench T1. When the semiconductor device includes the conductive member 50, a space is caused to remain between the insulating member 40 positioned at the two sidewalls of the first trench T1; and the conductive member 50 is formed in the space.

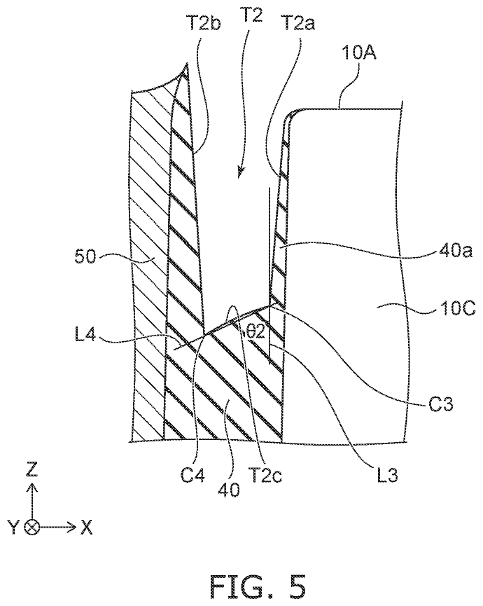

As shown in FIG. 5, the method for manufacturing the semiconductor device of the embodiment includes a process of forming a second trench T2 in the insulating member 40. The second trench T2 is formed by dry etching. For example, the second trench T2 is formed by RIE. The conditions of the RIE are set so that the sputtered material is easily deposited on the sidewalls of the second trench T2. As a result, the sidewalls of the second trench T2 are oblique to the first direction Z so that the width in the second direction X of the second trench T2 decreases downward.

The second trench T2 includes a first sidewall T2a facing the side surface of the mesa part 10C in the second direction X, a second sidewall T2b positioned at the side opposite to the first sidewall T2a in the second direction X, and a bottom wall T2c connecting the first sidewall T2a and the second sidewall T2b. The fluctuation of the depth of the first sidewall T2a when forming the second trench T2 corresponds to the fluctuation of the position Z_{C1} in the first direction Z of the first corner portion C1 of the gate electrode 30 described above, and affects the Qgd fluctuation.

In the second direction X, the second sidewall T2b is positioned more proximate to the interface between the conductive member 50 and the insulating member 40 than the first sidewall T2a. In the state shown in FIG. 4 before forming the second trench T2, the thickness in the first direction Z of the insulating member 40 at the mesa part 10C side is greater than the thickness in the first direction Z of the insulating member 40 at the conductive member 50 side. Therefore, in the second trench T2 as shown in FIG. 5, the depth in the first direction Z at the mesa part 10C side becomes less than the depth in the first direction Z at the conductive member 50 side. In other words, the position in the first direction Z of the lower end of the second sidewall T2b is positioned lower than the position in the first direction Z of the lower end of the first sidewall T2a.

Accordingly, the bottom wall T2c is oblique to the first and second sidewalls T2a and T2b. The second trench T2 includes a third corner portion C3 positioned between the first sidewall T2a and the bottom wall T2c, and a fourth corner portion C4 positioned between the second sidewall T2b and the bottom wall T2c. The position in the first direction Z of the fourth corner portion C4 is positioned lower than the position in the first direction Z of the third corner portion C3.

An angle θ2 between a third straight line L3 and a fourth straight line L4 is not more than 60°, wherein the third straight line L3 is a straight line extending in the first direction Z and passing through the third corner portion C3 of the second trench T2, and the fourth straight line L4 is a straight line passing through the third and fourth corner portions C3 and C4. The angle θ2 of the second trench T2 corresponds to the angle θ1 of the gate electrode 30 described above because the gate electrode 30 is formed inside the second trench T2 as described below.

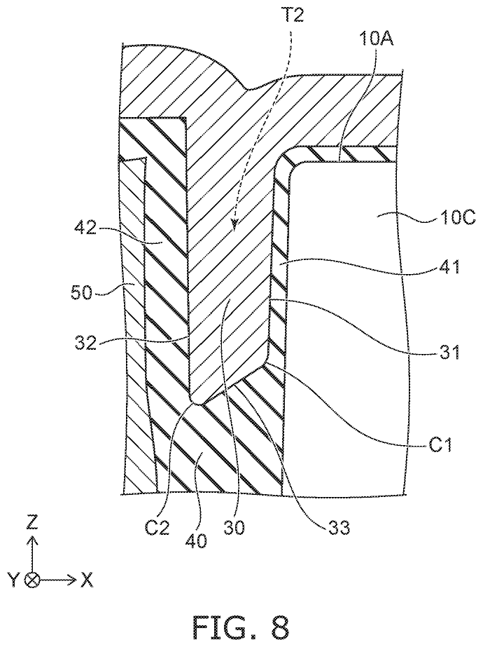

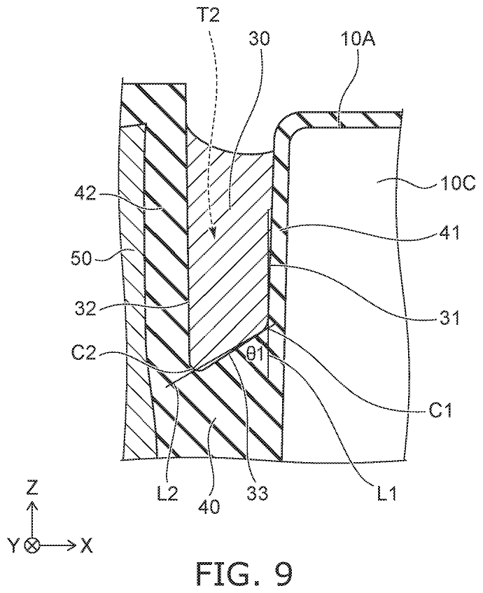

As shown in FIG. 8, the method for manufacturing the semiconductor device of the embodiment includes a process of forming the gate electrode 30 inside the second trench T2. For example, the gate electrode 30 is formed by CVD (Chemical Vapor Deposition). For example, the gate electrode 30 is etched-back by CDE (Chemical Dry Etching) after being deposited above the first surface 10A in the first direction Z. As a result, as shown in FIG. 9, the upper surface of the gate electrode 30 recedes to a prescribed position inside the second trench T2.

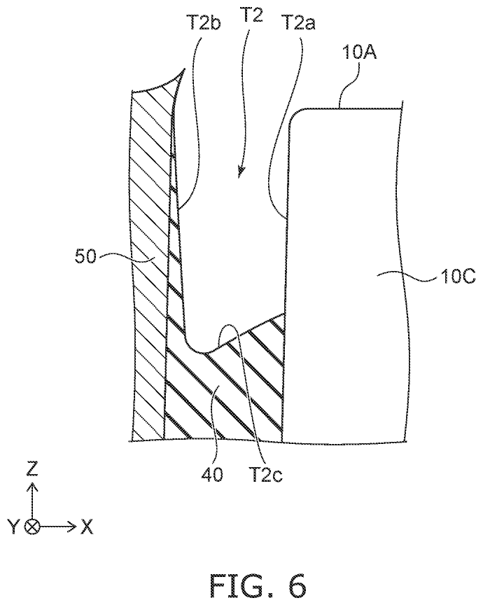

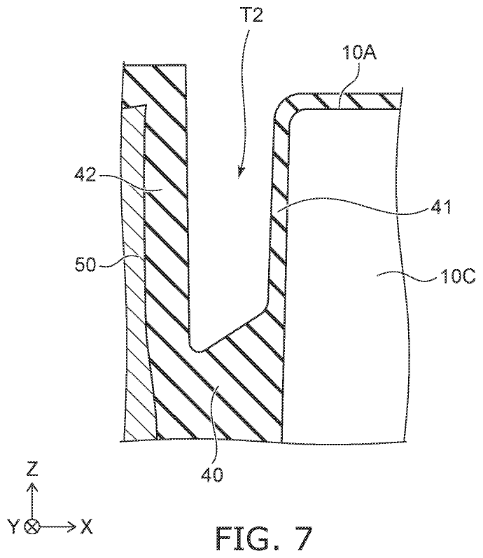

In the process of forming the second trench T2 described above, a portion 40a of the insulating member 40 remains between the first sidewall T2a and the side surface of the mesa part 10C as shown in FIG. 5. The method for manufacturing the semiconductor device of the embodiment may include a process of exposing the side surface of the mesa part 10C at the first sidewall T2a as shown in FIG. 6 by removing the portion 40a of the insulating member 40 between the first sidewall T2a and the side surface of the mesa part 10C after forming the second trench T2. The method for manufacturing the semiconductor device of the embodiment also may include a process of forming the first insulating part 41 on the exposed side surface of the mesa part 10C as shown in FIG. 7. As a result, the first insulating part 41 that is not damaged by RIE can be used as the gate insulating film instead of the portion 40a of the insulating member 40 that is damaged by RIE when forming the second trench T2.

For example, the portion 40a of the insulating member 40 between the first sidewall T2a and the side surface of the mesa part 10C can be removed by wet etching. As a result, the damage of the semiconductor layer 10 can be reduced compared to when the portion 40a of the insulating member 40 is removed by dry etching. The first insulating part 41 can be formed by thermal oxidation treatment of the exposed side surface of the mesa part 10C.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a semiconductor layer including
a first semiconductor part of a first conductivity type,
a second semiconductor part located on the first semiconductor part, the second semiconductor part being of a second conductivity type,
a third semiconductor part located on the second semiconductor part, the third semiconductor part being of the first conductivity type, and
a mesa part including the third semiconductor part, the second semiconductor part, and a portion of the first semiconductor part, the mesa part extending in a first direction;
a gate electrode facing a side surface of the mesa part; and
a first insulating part located between the gate electrode and the side surface of the mesa part,
the gate electrode including
a first side surface portion facing a region of the side surface of the mesa part including at least the second semiconductor part,
a second side surface portion positioned at a side opposite to the first side surface portion in a second direction orthogonal to the first direction,
a bottom portion oblique to the first and second side surface portions, the bottom portion connecting the first side surface portion and the second side surface portion,
a first corner portion positioned between the first side surface portion and the bottom portion, and
a second corner portion positioned between the second side surface portion and the bottom portion,
an angle between a first straight line and a second straight line being not more than 60°,
the first straight line being a straight line extending in the first direction and passing through the first corner portion,
the second straight line being a straight line passing through the first and second corner portions.

2. The device according to claim 1, wherein
the angle between the first straight line and the second straight line is not more than 40°.

3. The device according to claim 1, further comprising:
a conductive member facing the second side surface portion of the gate electrode in the second direction and extending further downward in the first direction than the bottom portion of the gate electrode; and
a second insulating part positioned between the conductive member and the second side surface portion.

4. The device according to claim 3, further comprising:
a first electrode located on the mesa part,
the first electrode being electrically connected with the third semiconductor part,
the conductive member being electrically connected with the first electrode.

5. The device according to claim 1, wherein
a position in the first direction of an upper end of the first side surface portion is positioned further toward the third semiconductor part side than a boundary between the second semiconductor part and the third semiconductor part.

6. The device according to claim 1, wherein
a length in the first direction of the second side surface portion is greater than a length in the first direction of the first side surface portion.

7. The device according to claim 1, wherein
an angle between the first side surface portion and the bottom portion inside the gate electrode is greater than 90°.

8. The device according to claim 1, wherein
an angle between the second side surface portion and the bottom portion inside the gate electrode is less than 90°.

9. The device according to claim 1, wherein
a maximum thickness in the second direction of the first insulating part between the first side surface portion of the gate electrode and the side surface of the mesa part is less than a maximum thickness in the second direction of the first insulating part between the bottom portion of the gate electrode and the side surface of the mesa part.

10. A method for manufacturing a semiconductor device, the method comprising:
forming a first trench in a semiconductor layer, and forming a mesa part of the semiconductor layer adjacent to the first trench in a second direction orthogonal to a first direction, the semiconductor layer including a first surface and a second surface, the second surface being positioned at a side opposite to the first surface in the first direction, the first trench extending in the first direction from the first surface;
forming an insulating member inside the first trench;
forming a second trench in the insulating member by dry etching, the second trench including a first sidewall facing a side surface of the mesa part in the second direction, a second sidewall positioned at a side opposite to the first sidewall in the second direction, a bottom wall oblique to the first and second sidewalls, a third corner portion positioned between the first sidewall and the bottom wall, and a fourth corner portion positioned between the second sidewall and the bottom wall, the bottom wall connecting the first sidewall and the second sidewall, an angle between a third straight line and a fourth straight line being not more than 60°, the third straight line being a straight line extending in the first direction and passing through the third corner portion, the fourth straight line being a straight line passing through the third and fourth corner portions; and
forming a gate electrode inside the second trench.

11. The method according to claim 10, wherein
a portion of the insulating member remains between the first sidewall and the side surface of the mesa part in the forming of the second trench, and
the method further comprises:
exposing the side surface of the mesa part at the first sidewall by removing the portion of the insulating member between the first sidewall and the side surface of the mesa part after the forming of the second trench; and
forming a first insulating part at the exposed side surface of the mesa part.

12. The method according to claim 11, wherein
the portion of the insulating member between the first sidewall and the side surface of the mesa part is removed by wet etching.

13. The method according to claim 11, wherein
the first insulating part is formed by thermal oxidation treatment of the exposed side surface of the mesa part.
